(19) United States
(12) Patent Application Publication
(10) Pub. No.: US 2012/0028408 A1
(43) Pub. Date: Feb. 2, 2012

(54) DISTRIBUTOR HEATER

(76) Inventors: Christopher Baker, Maumee, OH (US); Weixin Li, Waterville, OH (US)

(21) Appl. No.: 13/195,567

(22) Filed: Aug. 1, 2011

Related U.S. Application Data
(60) Provisional application No. 61/369,528, filed on Jul. 30, 2010.

(51) Int. Cl. H01L 31/0272; H01C 17/02; H05B 3/10; B23P 19/00; C23C 16/448; C23C 16/455

(52) U.S. Cl. 438/95; 427/255.23; 118/726; 219/553; 29/428; 29/611; 257/E31.008

(57) ABSTRACT

A vapor distributor assembly may include a carbon fiber heating element.

### CLAIM FOR PRIORITY

This application claims priority under 35 U.S.C. §119(e) to Provisional U.S. Patent Application Ser. No. 61/369,528, filed on Jul. 30, 2010, which is hereby incorporated by reference in its entirety.

### TECHNICAL FIELD

The present invention relates to photovoltaic devices and methods of production.

### BACKGROUND

During the manufacturing of a photovoltaic device, semiconductor material may be deposited on a glass substrate. This may be accomplished by vaporizing the semiconductor material and directing the vapor towards the glass substrate surface, such that the vapor condenses and is deposited on the glass, forming a solid semiconductor film. Current apparatuses and methods for depositing semiconductor material can be inefficient due to aspects of their design.

### DESCRIPTION OF DRAWINGS

FIG. 1 is a schematic of a system for depositing material on a substrate.

FIG. 2 is a schematic of a system for depositing material on a substrate.

FIG. 3 is a cross-sectional view distributor assembly.

FIG. 4 is a schematic of a distributor assembly proximate to a substrate.

FIG. 5 is a cross-sectional view of a distributor assembly.

FIG. 6 is a cross-sectional view of a distributor assembly.

FIG. 7 is a cross-sectional view of a distributor assembly.

FIG. 8 is a cross-sectional view of a distributor assembly.

FIG. 8A is a cross-sectional view of a distributor assembly.

FIG. 9 is a cross-sectional view of a distributor assembly.

FIG. 10 is a cross-sectional view of a distributor assembly.

FIG. 11 is a cross-sectional view of a distributor assembly.

### DETAILED DESCRIPTION

Photovoltaic devices can include multiple layers created on a substrate (or superstrate). For example, a photovoltaic device can include a barrier layer, a transparent conductive oxide (TCO) layer, a buffer layer, and a semiconductor layer formed in a stack on a substrate. Each layer may in turn include more than one layer or film. For example, the semiconductor layer can include a first film including a semiconductor window layer formed on the buffer layer and a second film including a semiconductor absorber layer formed on the semiconductor window layer. Additionally, each layer can cover all or a portion of the device and/or all or a portion of the layer or substrate underlying the layer. For example, a “layer” can include any amount of any material that contacts all or a portion of a surface.

The layers in a photovoltaic module can be formed from a solid material, such as a semiconductor powder, which can be introduced into a heated chamber of a vapor transport deposition system, along with a carrier gas, where the solid material can be vaporized. Vapor transport deposition systems are described in U.S. application Ser. No. 11/380,073, filed Apr. 25, 2006, U.S. application Ser. No. 11/380,079, filed Apr. 25, 2006, U.S. application Ser. No. 11/380,088, filed Apr. 25, 2006, and U.S. application Ser. No. 11/380,095, filed Apr. 25, 2006, each of which is incorporated by reference in its entirety. The vapor and carrier gas can then pass through the walls of the heated permeable chamber into a shroud surrounding the chamber. The shroud can include an opening through which the vapor may be directed toward a surface of a substrate, such as a glass substrate, where it may be deposited as a film.

A critical component of vapor transport deposition systems is the heating element. Existing systems use silicon carbide due to its wide availability as an industrial heating material, as well as its porous structure. But silicon carbide can break down due to its silicon component, complicating control of the deposition process. Carbon fiber (or graphite fiber) is a porous material consisting of thin fibers of about 5 to 10 μm in diameter, and is composed mostly of carbon atoms. The fibers can be twisted together to form a porous material, which can be lighter than aluminum, and stronger than steel. Carbon fiber can have a high tensile strength, low weight, and low thermal expansion, which can be suitable attributes for a heating material in a vapor transport deposition system. Given its similar properties to silicon carbide (but with less risk of silicon contamination), carbon fiber is a suitable material for distributor design.

In one aspect, a vapor distributor assembly may include a heating element configured to provide a temperature sufficient to vaporize at least a portion of a solid material to form a vapor. The heating element may include a carbon-based structure. The carbon-based structure can include carbon fiber. The carbon-based structure can include carbon nanotubes.

The heating element may be configured to be resistively heated through application of a current. The heating element may be housed within a first chamber. The heating element may be configured to maintain the first chamber at a temperature of about 400 degrees C. or more. The heating element may be configured to maintain the first chamber at a temperature of about 800 degrees C. or less. The first chamber may be configured to receive a solid material and a carrier gas. The first chamber may include one or more distribution holes. The vapor distributor assembly may include a second chamber substantially proximate to the first chamber. The second chamber may be configured to provide a material flow sufficiently indirect to mix the vapor and the carrier gas into a substantially uniform gas composition. The first and second chambers may be substantially tubular. The first chamber may be disposed within the second chamber such that the second chamber sheaths the first chamber. The second chamber may include one or more distribution holes. The first chamber may be configured such that substantially no solid material can be directed into the second chamber.

In another aspect, a method for depositing material on a substrate may include introducing a solid material and a carrier gas into a first chamber. The first chamber may include a heating element. The method may include resistively heating the heating element to vaporize the solid material into a vapor. The heating element may include a carbon-based structure including carbon fiber and/or carbon nanotubes. The method may include directing a mixture of the vapor and carrier gas through a second chamber to form a substantially uniform gas composition. Directing the mixture of vapor and carrier gas can form a substantially uniform gas composition. The method may include directing the substantially uniform gas composition toward a surface of a substrate having a temperature lower than the vapor.

In another aspect, a system for depositing a film on a substrate can include a material source connected to a distributor assembly such that a solid material and carrier gas supplied by the material source are introduced into the distributor assembly. The distributor assembly can include a first chamber, such that the solid material and carrier gas introduced into the distributor assembly are directed into the first chamber. The distributor assembly can include a heating element positioned within the first chamber and providing a temperature high enough that at least a portion of the solid material vaporizes into a vapor. The heating element can include a plurality of carbon-based structures including carbon fibers and/or carbon nanotubes. The distributor assembly can include a second chamber proximate to the first chamber and providing a material flow sufficiently indirect to mix the vapor and the carrier gas into a substantially uniform vapor/carrier gas composition. The distributor assembly can include an outlet proximate to the second chamber and positioned in a manner that the uniform vapor/carrier gas composition toward a surface of a proximate substrate. The system can include a conveyor for transporting the substrate sufficiently proximate to the distributor assembly such that the vapor may be deposited on the substrate as a film.

In another aspect, a method of manufacturing a photovoltaic module can include positioning a substrate at a substrate position within a process chamber and introducing a solid material and a carrier gas into a first chamber, the first chamber comprising a heating element and positioned adjacent to the process chamber. The method can include heating the heating element to vaporize the solid material into a vapor. The heating element can include a plurality of carbon-based structures including carbon nanotubes and/or carbon fibers.

The method can include directing a mixture of the vapor and carrier gas through a second chamber. The method can include forming a substantially uniform gas composition from the vapor and carrier gas. The method can include directing the substantially uniform gas composition into the process chamber and toward a surface of the substrate. The substrate can have a temperature lower than the vapor, to deposit a film comprising the solid material on the substrate. The solid material can include cadmium telluride.

The method can include depositing one or more additional layers adjacent to the layer of solid material deposited on the substrate. The method can include forming a back contact layer adjacent to the layer of solid material deposited on the substrate. The method can include positioning at least one common conductor adjacent to the back contact layer. The method can include positioning a back cover adjacent to the back contact layer. The method can include accessing the at least one common conductor through an opening on the back cover. The method can include positioning a junction box adjacent to the back cover.

In another aspect, a method of manufacturing a vapor distributor assembly can include positioning a heating element including a carbon-based structure adjacent to a first chamber. Positioning the heating element adjacent to a first chamber can include positioning the heating element at least partially within the interior of the first chamber. The method can include positioning a second heating element adjacent to a second chamber. The method can include positioning a material source adjacent to the first chamber to create a material flow path between the material source and the first chamber. The method can include positioning the first chamber adjacent to a substrate process chamber configured to accept a substrate to accept material from the first chamber. The method can include positioning the first chamber adjacent to the substrate process chamber comprises positioning the first chamber at least partially within the interior of the process chamber.

In another aspect, a method of creating a heating element can include arranging one or more carbon-based structures into the form of a heating element. The one or more carbon-based structures can include carbon nanotubes and/or carbon fibers. The method can include the step of forming the carbon-based structures before creating the heating element. The method can include the step of forming the carbon-based structures comprises arranging a plurality of carbon atoms into the carbon-based structures. The method can include fixing the carbon atoms into carbon-based structures after arranging the carbon atoms.

In another aspect, a vapor distributor assembly can include a heating element configured to provide a temperature sufficient to vaporize at least a portion of a solid material to form a vapor, the heating element comprising a fiber. The fiber can include a carbon fiber. The fiber can include a glass fiber. The vapor distributor assembly can include at least one chamber adjacent to the heating element, wherein the at least one chamber is configured to direct a vaporized solid material and carrier gas toward a substrate.

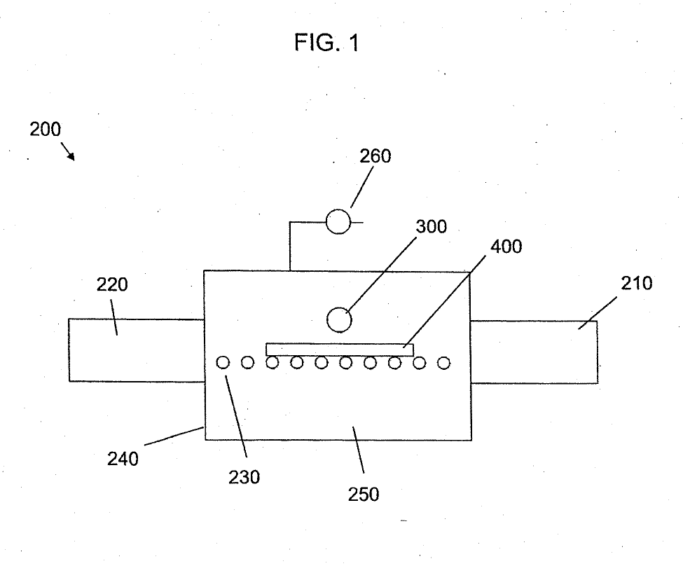

Referring to FIG. 1, a vapor transport deposition system 200 may include a distributor assembly 300. System 200 may include a housing 240 defining a processing chamber 250 in which a material (e.g., a semiconductor material) may be deposited on a substrate 400. Substrate 400 may include any suitable substrate material, including, for example, a glass (e.g., soda-lime glass). Housing 240 may include an entry station 220 and an exit station 210. Entry station 220 and exit station 210 can be constructed as load locks or as slit seals through which substrate 400 may enter and exit the processing chamber 250. The housing 240 can be heated in any suitable manner such that its processing chamber can be maintained at a temperature suitable for deposition. For example, distributor assembly 300 may include a heating element which may be resistively heated by passing of a current. The heating element may consist of any suitable material, including, for example, carbon fiber. The heating element of distributor assembly 300 may be heated to any suitable deposition temperature. For example, the distributor assembly 300 (via heating from a heating element included therein) may have a temperature of more than about 400 degrees C., more than about 500 degrees C., more than about 650 degrees C., less than about 1200 degrees C., less than about 950 degrees C., or less than about 700 degrees C. For example, the temperature of distributor assembly 300 can be about 500 degrees C. to about 1200 degrees C. During processing, substrate 400 may be heated to any desired substrate temperature, including, for example, more than about 100 degrees C., more than about 200 degrees C., more than about 300 degrees C., less than about 800 degrees C., or less than about 700 degrees C. Substrate 400 can be transported by any appropriate means, including, for example, by rollers 230, or a conveyor belt, which may be driven by an attached electric motor.

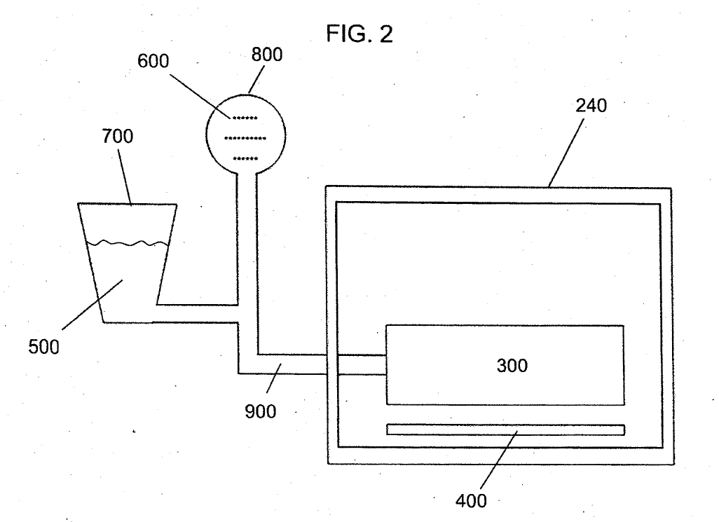

Referring now to FIG. 2, distributor assembly 300 contained in housing 240 may be connected by a feed tube 900 to a material supply, which can include any suitable means for delivering material to distributor assembly 300. For example, feed tube 900 may be connected to a hopper 700, containing a powder 500, and a carrier gas source 800, containing an appropriate carrier gas 600. Powder 500 can contact carrier gas 600 in feed tube 900, and both carrier gas 600 and powder 500 may be introduced into distributor assembly 300. Powder 500 may include any desired material, including, for example, any desired semiconductor material for fabrication of one or more photovoltaic devices. For example, powder 500 may contain quantities of cadmium and/of tellurium. Carrier gas 600 may include any suitable carrier gas, including, for example, helium.

After carrier gas 600 and powder 500 are introduced into distributor assembly 300, powder 500 may be vaporized and directed through distributor assembly 300 along with carrier gas 600 in such a manner that carrier gas 600 and the vapor may be mixed to form a uniform vapor/carrier gas composition. The uniform vapor/carrier gas composition may then be directed out of distributor assembly 300 toward substrate 400. Substrate 400 may have a substantially lower temperature than that of distributor assembly 300. The lower temperature of substrate 400 may cause condensation of the vapor on a surface of substrate 400, and the deposition of a film, which may have a substantially uniform thickness and a substantially uniform structure demonstrating a uniform crystallization and a substantial absence of particulate material, such as unvaporized powder.

The exit point of the semiconductor vapor from distributor assembly 300 can be spaced from substrate 400 at a distance in any suitable range, including for example, more than about 0.5 cm, more than about 2 cm, more than about 4 cm, less than about 10 cm, less than about 7 cm, or less than about 5 cm. While large spacing can be utilized, such distance may require lower system pressures and may result in material waste due to overspraying. Spacing that is too small can cause problems due to thermal warpage of substrate 400 during conveyance in the proximity of the higher temperature distributor assembly 300. Substrate 400 can pass proximate to the point where the semiconductor vapor exits distributor assembly 300 at any suitable speed, including, for example, about 20 mm per second to about 40 mm per second.

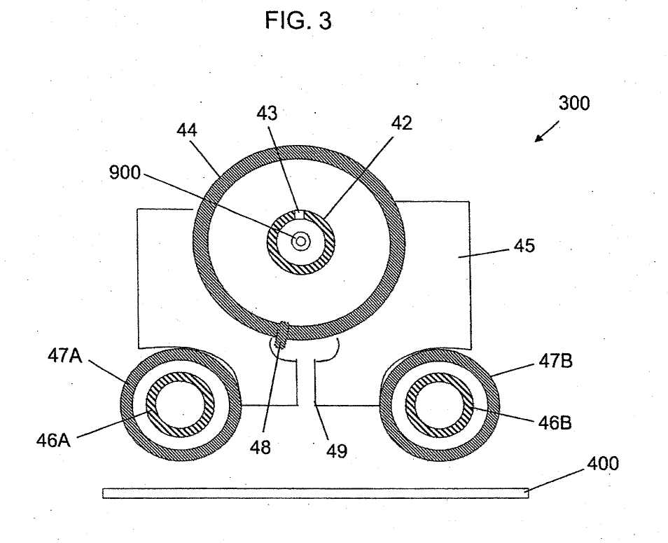

FIG. 3 depicts an embodiment of a distributor assembly 300 with a carbon fiber heating element (e.g., heater tube 42). A carrier gas and powder may be introduced into distributor assembly 300 through feed tube 900. Feed tube 900 may consist of any suitable material, including, for example, mullite, and may have any suitable configuration, including, for example, an outer diameter of about 5 mm to about 15 mm, and an inner diameter of about 5 mm to about 10 mm. The carrier gas and powder may be first directed into the interior of a first chamber, heater tube 42, which can be impermeable and can have any suitable configuration, including, for example, an outer diameter of about 15 mm to about 54 mm, and an inner diameter of about 10 mm to about 15 mm. Heater tube 42 can include any suitable material, including, for example, one or more carbon-based structures, such as carbon fibers or carbon nanotubes. Heater tube 42 can include any other suitable material, such as a fibrous material, for example, carbon fiber or mineral fibers such as glass fiber. Heater tube 42 may be heated in any suitable manner. For example, heater tube 42 can be resistively heated by applying a current across heater tube 42. Alternatively, heater tube 42 may be heated by placing one or more heating elements proximate to the heater tube. For example, one or more heating elements may be placed in contact with heater tube 42. The heating elements can include any suitable material, such as a ceramic material, and can themselves be heated in any suitable manner, for example, by resistive heating. Multiple (e.g., two, or three, or any suitable number) heating elements can be placed parallel to each other along a dimension (such as a length) of heater tube 42. Alternatively, a coil heater may be wrapped around heater tube 42.

Heater tube 42 can be heated to any suitable deposition temperature, including, for example, more than about 400 degrees C., more than about 550 degrees C., more than about 700 degrees C., less than about 1200 degrees C., less than about 950 degrees C., or less than about 800 degrees C. Heater tube 42 may also be heated to a substantially high temperature (i.e., from about 1200 degrees C. to about 1500 degrees C.). Higher temperatures, such as this may be used to vaporize solid materials more quickly.

As the solid material and carrier gas are introduced into heater tube 42, the vapor and carrier gas may be directed out of heater tube 42 through outlet 43, which can be a single hole, and which can have any suitable configuration, including, for example, a diameter of about 2 mm to about 20 mm, into a second chamber, distribution manifold 44. Outlet 43 can also represent a plurality of distribution holes. Distribution manifold 44 can be composed of any suitable material, including, for example, graphite, mullite, or another suitable ceramic, and can have any suitable configuration, including, for example, an outer diameter of about 75 min to about 100 mm and an inner diameter of about 50 mm to about 80 mm.

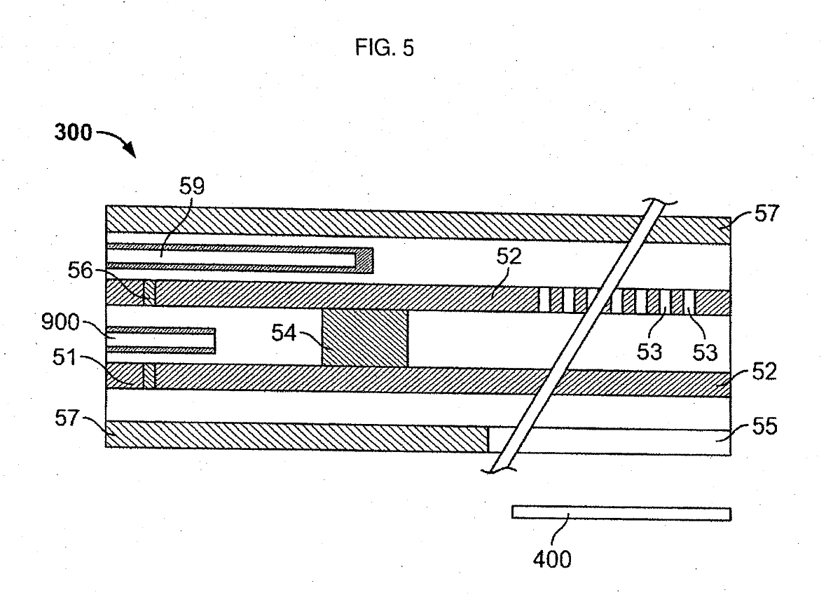

Distribution manifold 44 may be positioned above glass substrate 400 by a cradle 45, which can be formed from graphite, such that the length of distribution manifold 44 covers at least a portion of the width of substrate 400 as substrate 400 is conveyed beneath distribution manifold 44. The vapor and carrier gas can travel within and along the length of distribution manifold 44 until the vapor and carrier gas form a uniform vapor/carrier gas composition. The uniform vapor/carrier gas composition may be directed out of distribution manifold 44 through a plurality of distribution holes 48 aligned in a row along the length of distribution manifold 44. Distribution holes 48 can number about 20 to about 50 and can have a diameter of about 1 mm to about 5 mm. The number of distribution holes 48 included in distributor assembly 300 can be varied as required, and can be spaced from about 19 mm to about 25 mm apart. The uniform vapor/carrier gas composition may then be directed into a nozzle 49 formed by graphite cradle 45, after which the vaporized semiconductor may be deposited on underlying substrate 400, which can be a glass sheet substrate. Directing the uniform vapor/gas composition streams emitted from distribution holes 48 into a portion of cradle 45, as depicted in FIG. 5, may disperse the uniform vapor/gas composition and further increase its uniformity of composition, pressure, and velocity in preparation for deposition on underlying substrate 400.

As shown in FIG. 3, graphite cradle 45 may be heated by adjacently positioned tubes 47A and 47B, which can be formed from mullite and which may shroud secondary heater tubes 46A and 46B, respectively, which may also contain heated carbon fiber tubes, and which may have any suitable configuration, including, for example, an outer diameter of about 25 mm to about 75 mm. As substrate 400 is conveyed by the orifice of nozzle 49 a film may be formed on the surface of substrate 400, adjacent to the nozzle. The proximity of substrate 400 to nozzle 49 may increase the efficiency of depositing the film by reducing the amount of material wasted.

A carbon fiber tube included in heater tube 42 can be manufactured using a variety of techniques, including, for example, any suitable roll-wrapping method. A number of parameters may be controlled during manufacturing of the fiber tube to achieve desired electrical and physical requirements, including, for example, the angle and wall thickness of the fiber. The resistivity of a component formed from carbon fiber can be controlled to provide the required temperature in a resulting resistance-heated heater tube 42. To make carbon nanotubes into heater tubes, any suitable ceramic fabrication method may be used, including, for example, molding and casting. Carbon nanotubes can be chemically activated (for example, fluorinated) to allow them to crosslink with each other during formation of a larger carbon nanotube structure, such as heater tube 42.

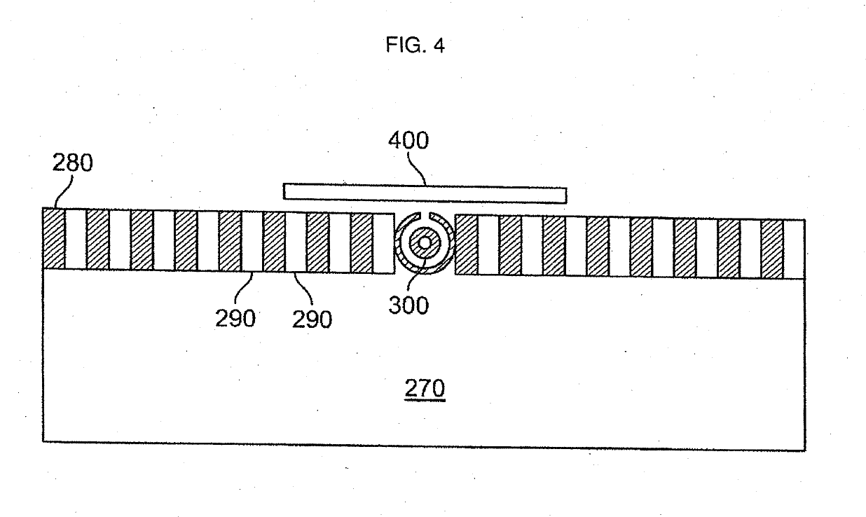

FIG. 4 represents an alternative embodiment of system 200 in which a semiconductor film may be deposited on a downward-facing surface of substrate 400. The alternate system depicted includes a refractory hearth 280 above a plenum 270 of heated pressurized gas. Holes 290 in hearth 280 provide for upward flow of the pressurized heated gas so as to support glass substrate 400 in a floating manner. As floating glass substrate 400 is conveyed along the length of hearth 280, the downward-facing surface passes proximate to distributor assembly 300, from which semiconductor vapor is directed toward and deposited as a film on substrate 400.

FIG. 5 depicts one embodiment of distributor assembly 300. FIG. 5 depicts a cross section view taken along the length of a distributor assembly 300. A carrier gas and a powder are introduced through feed tube 900 into heater tube 52. Heater tube 52 can be resistively heated by applying current across the length of heater tube 52 and is and can be formed from any suitable material, such as a carbon-based structure including carbon fibers and/or carbon nanotubes. The powder and carrier gas are heated in heater tube 52, causing the powder to vaporize. The vapor and carrier gas are then directed through filter 54 provided in heater tube 52. Filter 54 can be formed from a material that is permeable to the carrier gas and vapor, but not to the powder, thereby ensuring that no powder is ultimately deposited on the substrate. Heater tube 52 may be joined by internal joints 56 to low-resistance electrified ends 51, which are not permeable.

After the vapor and carrier gas are directed through filter 54, the mixture is directed into a portion of heater tube 52 having a plurality of outlets 53, which are preferably holes drilled in a line on one side of heater tube 52. The vapor and carrier gas are then directed through outlets 53 into the interior of an outer tubular sheath 57 which shrouds heater tube 52. Outer tubular sheath 57 can be formed from mullite. During the passage through heater tube 52 and into and within outer tubular sheath 57, the irregular flow of the vapor and carrier gas results in continuous mixing and diffusion of the vapor and the carrier gas to provide a uniform vapor/carrier gas composition. As shown in FIG. 5, the interior of outer tubular sheath 57 can include a thermowell 59 for monitoring the temperature of distributor assembly 300.

It should be appreciated that FIG. 5 depicts a portion of distributor assembly 300 and an additional feed tube and internal filter may be provided at an opposite end of distributor assembly 300, which is not shown in FIG. 5.

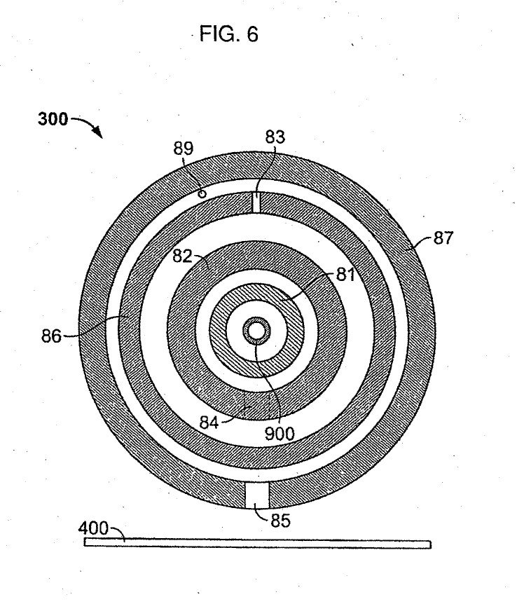

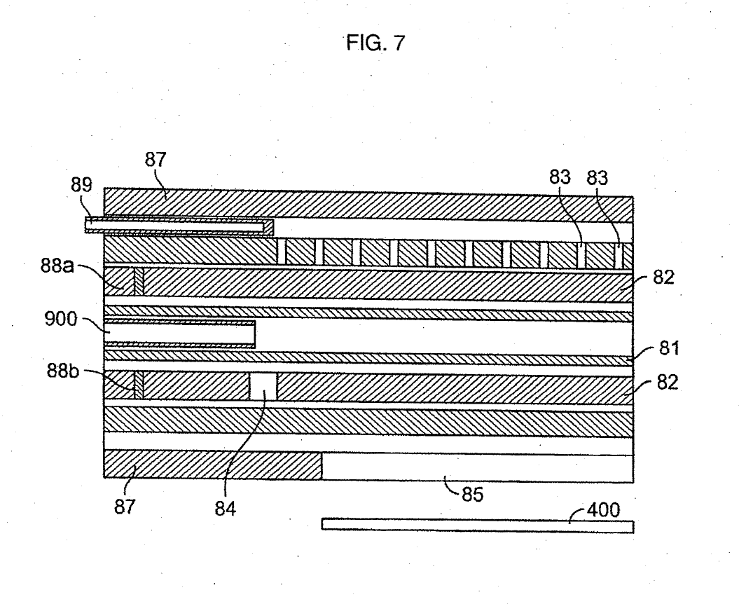

Referring now to FIG. 6 and FIG. 7, an alternate embodiment of distributor assembly 300 is depicted. A powder and carrier gas are introduced into distributor assembly 300 through feed tube 900. The powder and carrier gas are first directed into a filter tube 81 positioned inside heater tube 82. Heater tube 82 heats filter tube 81 to a temperature sufficient to vaporize the powder inside filter tube 81. Filter tube 81 can also be heated (for example, resistively heated) and can have an outer diameter of about 20 mm to about 40 mm (preferably about 30 mm), and an inner diameter of about 10 mm to about 20 mm (preferably about 16 mm). Heated tube 81 is permeable to the vapor, so the vapor and carrier gas permeate filter tube 81 and are directed into heater tube 82. Filter tube 81 can be formed from any suitable material. For example, filter tube 81 may be formed from silicon carbide. Alternatively, filter tube 81 may be formed from carbon fiber or carbon nanotubes, which materials may confer reduced possibility of degradation compared to silicon carbide in some environments.

After the vapor and carrier gas permeate through filter tube 81 and into heater tube 82, the vapor and carrier gas travel within heater tube 82, which causes the vapor and carrier gas to mix. Heater tube 82 can be resistively heated and can be formed from and suitable material, such as a material formed from a plurality of carbon-based structures, such as carbon fibers and/or carbon nanotubes, or any other suitable material. Heater tube 82 can have an outer diameter of about 40 mm to about 55 mm (preferably about 50 mm), an inner diameter of about 35 mm to about 45 mm (preferably about 45 mm), and may be attached to low-resistance electrified ends 88a of distributor assembly 300 by internal joints 88b (see FIG. 7).

As new vapor and carrier gas permeate into heater tube 82 from filter tube 81, the mixed vapor and carrier gas are directed out of heater tube 82 through outlet 84, which can be a single drilled hole located near one end of heater tube 82, and which can have a diameter of about 10 mm to about 15 mm (preferably about 13 mm). The vapor and carrier gas are directed through outlet 84, which causes the vapor and carrier gas to continue to mix while entering a first flow path defined by the exterior of heater tube 82 and the interior of manifold 86, which can be formed from graphite and which can have an outer diameter of about 75 mm to about 100 mm (preferably about 86 mm), and an inner diameter of about 60 mm to about 80 mm (preferably about 70 mm).

The flow of the vapor and carrier gas in the first flow path causes the vapor and carrier gas to continue to mix and form a uniform vapor/carrier gas composition. The vapor and carrier gas are directed through the first flow path from drilled hole 84 on one side of heater tube 82 around heater tube 82 inside manifold 86 to a plurality of distribution holes 83 positioned in a line along the length of manifold 86 on a side of manifold 86 substantially opposite the side of heater tube 82 where drilled hole 84 is located. A thermowell 89 is also provided proximate to heater tube 82 in order to monitor the temperature of distributor assembly 300.

The uniform vapor/carrier gas composition is directed from the first flow path out of manifold 86 through distribution holes 83 into the interior of outer tubular sheath 87, which can be formed from mullite, and which, along with the exterior of manifold 86 defines a second flow path. Distribution holes 83 can have a diameter of about 1 mm to about 5 mm (preferably about 3 mm). Travel of the uniform vapor/carrier gas composition through the second flow path disperses the streams of uniform vapor/carrier gas composition directed from distribution holes 83 and further increases the vapor/carrier gas uniformity of composition, pressure, and velocity. The uniform vapor/carrier gas composition is directed to slot 85 running along a portion of the length of outer tubular sheath 87, and located on a side of outer tubular sheath 87 substantially opposite the position on manifold 86 where distribution holes 83 are located. Outer tubular sheath 87 can be formed from mullite, and can have an outer diameter of about 80 mm to about 150 mm (preferably about 116 mm), and an inner diameter of about 60 mm to about 130 mm (preferably about 104 mm). After it is directed from the second flow path and distributor assembly 300 via slot 85, the vapor is deposited as a film on underlying substrate 400, which is conveyed past distributor assembly 300.

As with earlier embodiments, it should be noted that FIG. 77 depicts a portion of distributor assembly 300 and an additional feed tube and material source may be provided at an opposite end of distributor assembly 300, which is not shown in FIG. 7.

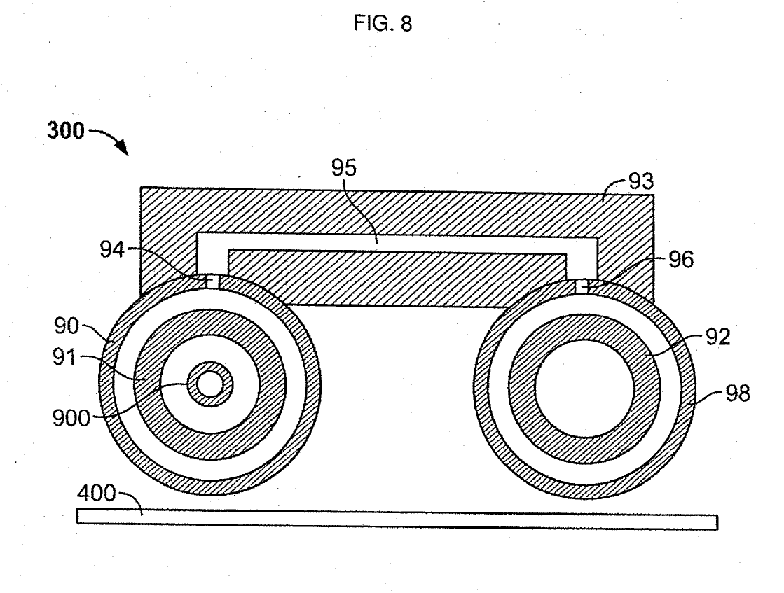

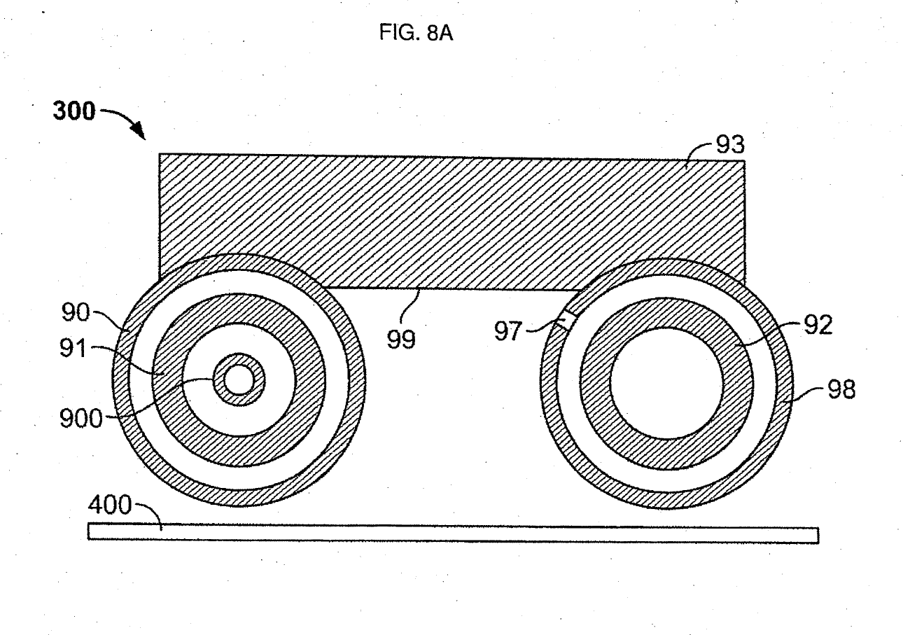

Referring now to FIG. 8, an alternate embodiment of a distributor assembly 300 in accordance with the present invention is depicted. A powder and a carrier gas are directed into the interior of first heater tube 91 via feed tube 900. First heater tube 91 is resistively heated to a temperature sufficient to vaporize the powder and is permeable to the resulting vapor and the carrier gas, but impermeable to the powder. Consequently, any powder that is not vaporized is unable to pass from the interior of first heater tube 91. First heater tube 91 can be formed from any suitable material, such as a carbon-based structure including carbon fibers and/or carbon nanotubes.

After the powder is vaporized to form a vapor, the vapor and carrier gas permeate the walls of first heater tube 91 and are directed to the space between first heater tube 91 and first tubular sheath 90, which can be formed from mullite, graphite, or cast ceramic. Passage within first tubular sheath 90 causes the vapor and carrier gas to mix to form a uniform vapor/carrier gas composition. The uniform vapor/carrier composition is directed through first outlet 94. First outlet 94 can be a single drilled hole and the vapor and carrier gas are further remixed as they pass through first outlet 94.

As shown in FIG. 8, the uniform vapor/carrier gas composition directed through first outlet 94 enters a first flow path 95, which leads to a second tubular sheath 98. First flow path 95 may be formed in a block 93, which in turn physically connects the interiors of first tubular sheath 90 and second tubular sheath 98, and which can be formed from mullite, graphite or cast ceramic. The uniform vapor/carrier gas composition is directed through first flow path 95 are then directed through inlet 96, which can be a single drilled hole formed in second tubular sheath 98, which can be formed from mullite.

The uniform vapor/carrier gas composition is directed within the interior of outer tubular sheath 57 and toward a slot 55, which is preferably located on the side of outer tubular sheath substantially opposite outlets 53 to provide a lengthy and indirect pathway for the vapor and carrier gas, thereby dispersing the streams of uniform vapor/carrier gas composition directed from outlets 53 and promoting maximum mixing and uniformity of gas composition, pressure and velocity. The uniform vapor/carrier gas composition is directed out of outer tubular sheath 57 through slot 55 and the film of material is deposited on underlying substrate 400.

Referring now to FIG. 8A, the uniform vapor/carrier gas composition is directed through a second flow path defined by the exterior of second heater tube 92 and the interior of second tubular sheath 98. Passage of the uniform vapor/carrier gas composition through the second flow path remixes the vapor and carrier gas, maintaining the uniform vapor/carrier gas composition. The uniform vapor/carrier gas composition is then directed from the second flow path out a plurality of terminal outlets 97, which can be drilled holes provided along at least a portion of the length of the second tubular sheath 98. The uniform vapor/carrier gas composition can be directed toward a vapor cap 99, which may include a downward-facing surface of block 93 and which, along with the first tubular sheaths 96 and second tubular sheath 98, defines a space (preferably about 1 to about 2 cm wide) spreads streams of the uniform vapor/carrier gas composition emitted from terminal outlets 97 and further increases the uniformity of the vapor/carrier gas with respect to composition, pressure, and velocity. The uniform vapor/carrier gas composition is consequently directed away from distributor assembly 300, towards underlying substrate onto which the vapor is deposited as a film.

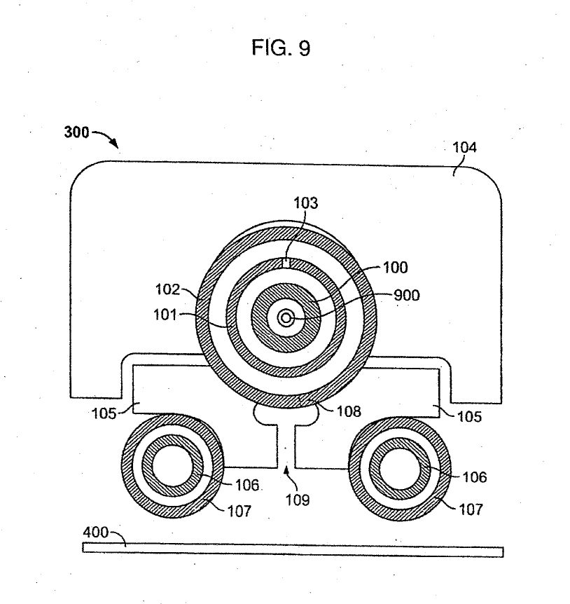

Referring now to FIG. 9, an alternate embodiment of a distributor assembly 300 is depicted. A powder and carrier gas are introduced into the interior of heater tube 100. Heater tube 100 is heated to a temperature sufficient to vaporize the powder as it travels within and along the length of heater tube 100. Heater tube 100 can be formed from any suitable material, such as a material formed from a plurality of carbon-based structures such as carbon fibers and/or carbon nanotubes. Heater tube 100 can be formed from a fibrous material. Heater tube 100 can be heated in any suitable manner. For example, heater tube 100 can be resistively heated. Heater tube 100 can be permeable to the vapor and carrier gas, but not to the powder. As the powder is vaporized in heater tube 100, it begins to form a uniform vapor/carrier gas composition with the carrier gas.

The vapor and carrier gas permeate through heater tube 100 into tubular sheath 101, which surrounds heater tube 100 and can be formed from mullite. The vapor and carrier gas are directed within tubular sheath 101, which causes the vapor and carrier gas to continually mix. The vapor and carrier gas are then directed toward outlet 103, which can be a single drilled hole formed in tubular sheath 101. As the vapor and carrier gas are directed through outlet 103, they are remixed even further, contributing to an increasingly uniform vapor/carrier gas composition.

The mixed vapor and carrier gas travel through outlet 103 into the interior of distribution manifold 102, which, like tubular sheath 101, can be formed from mullite or graphite. Distribution manifold 102 may be encased or surrounded by an insulation such as a fiber blanket insulation 104 for retaining heat generated by permeable heated tube 100, thereby reducing the energy required to maintain the temperature required to vaporize the powder. Distribution manifold 102 can be supported by a cradle 105, which can be formed from graphite or any other suitable material. Cradle 105 can be heated by external heater tubes 106 and 106, which can be formed from a material including carbon-based structures, such as carbon fibers and/or carbon nanotubes, and located inside external heater tube sheaths 107 and 107, which can be formed from mullite or any other suitable material and which can conduct heat generated by external heater tubes 106 and 106 to the adjacent cradle 105.

After the uniform vapor/carrier gas composition is directed through outlet 103 in tubular sheath 101, the vapor and carrier gas continue to mix as they are directed through the space between the interior wall of distribution manifold 102 and the exterior of tubular sheath 101. The uniform vapor/carrier gas composition is directed to a plurality of distribution holes 108 located at a position in distribution manifold 102 substantially opposite the position on tubular sheath 101 at which outlet 103 is located. The plurality of distribution holes 108 can be aligned along at least a portion of the length of distribution manifold 102. The uniform vapor/carrier gas composition is directed through distribution holes 108 toward a portion of graphite cradle 105, dispersing streams of uniform vapor/carrier gas composition directed through distribution holes 108 and further increasing the uniformity of the vapor/carrier gas with respect to composition, pressure, and velocity. In addition to heating graphite cradle 105, external heater tubes 106 and 106 are also proximate to nozzle 109 through which the uniform vapor/carrier gas composition is directed out of distributor assembly 300. Both the heating of cradle 105 and the proximity of external heater tubes 106 and 106 to uniform vapor/carrier gas composition exiting distributor assembly 300 at nozzle 109 maintains the uniform vapor/carrier gas composition at a temperature sufficient to maintain the vapor in a vapor state. A temperature of about 500 degrees C. to about 1200 degrees C. is sufficient to maintain the vapor in a vapor state, where the starting material is a cadmium chalcogenide.

As substrate 400 is conveyed by the orifice of nozzle 109, the uniform vapor/carrier gas composition is directed toward surface of substrate 400, which is maintained at a lower temperature such that the vapor condenses and is deposited on a surface of substrate 400 as a film.

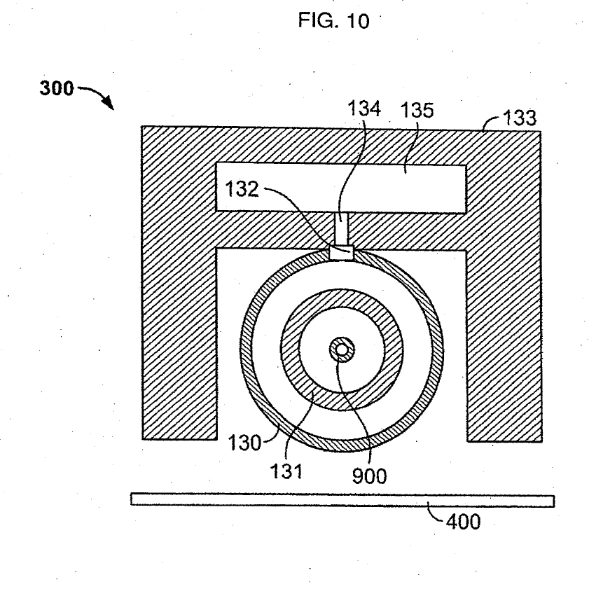

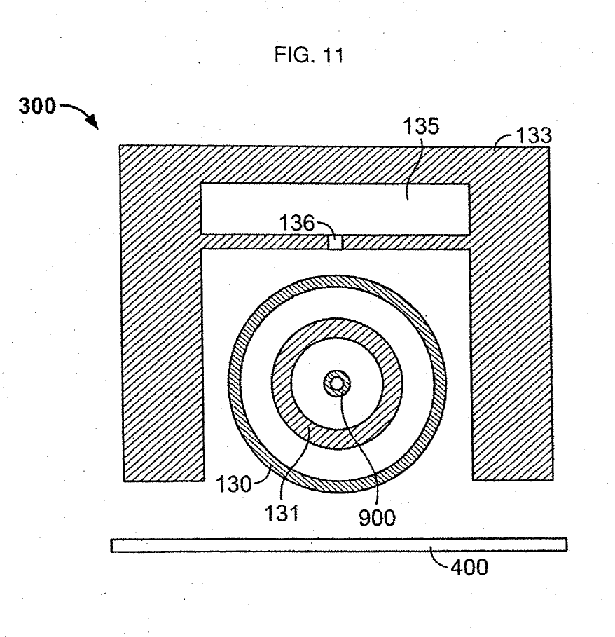

Referring now to FIG. 10 and FIG. 11, an alternate embodiment of a distributor assembly 300 is depicted. A powder and a carrier gas are directed into the interior of heater tube 131 via feed tube 900, which can be formed from mullite, and which can have an outer diameter of about 5 mm to about 15 mm (preferably about 10 mm), and an inner diameter of about 5 mm to about 10 mm (preferably about 6 mm). Heater tube 131 can be formed from any suitable material such as a material including carbon-based structures such as carbon fiber and/or carbon nanotubes and can be resistively heated to a temperature sufficient to vaporize the powder and is permeable to the resulting vapor and the carrier gas, but impermeable to the powder. Consequently, any powder that is not vaporized is unable to pass from the interior of heater tube 131. Heater tube 131 can have an outer diameter of about 30 to about 70 mm (preferably about 54 mm), and an inner diameter of about 25 mm to about 50 mm (preferably about 33 mm).

After the powder is vaporized to form a vapor, the vapor and carrier gas permeate the walls of heater tube 131 and are directed to the space between heater tube 131 and tubular sheath 130, which can be formed from graphite, mullite, or another suitable ceramic, and which has an outer diameter of about 60 mm to about 120 mm (preferably about 85 mm), and an inner diameter of about 50 mm to about 100 mm (preferably about 75 mm). Passage within tubular sheath 130 causes the vapor and carrier gas to mix to form a uniform vapor/carrier gas composition. The uniform vapor/carrier composition is directed through outlet 132 formed in tubular sheath 130. Outlet 132 can be a single drilled hole with a diameter of about 5 mm to about 20 mm (preferably about 13 mm) and the vapor and carrier gas are further remixed as they pass through outlet 132.

As shown in FIG. 10, the uniform vapor/carrier gas composition directed through outlet 132 is then directed through hole 134 with a diameter of about 5 mm to about 20 mm (preferably about 13 mm) and into passageway 135, formed in block 133, which can be made of graphite, or mullite, or another suitable ceramic. The uniform vapor/carrier gas composition is directed through passageway 135.

Referring now to FIG. 11, the uniform vapor/carrier gas composition directed through passageway 135 is directed out a plurality of distribution holes 136, which is formed in block 133 and which can be collinear to hole 134 along the length of block 133. Distribution holes 136 can be drilled, can have a diameter of about 1 mm to about 5 mm (preferably about 3 mm), and can number from about 10 to about 50 along the length of block 133, about 10 mm to about 25 mm (preferably about 19 mm) apart. The uniform vapor/carrier gas composition can be directed through distribution holes 136 toward a portion of tubular sheath 130, which disperses streams of uniform vapor/carrier gas composition directed from distribution holes 136 and further increases the uniformity of the vapor/carrier gas with respect to composition, pressure, and velocity. The uniform vapor/carrier gas composition is directed through a space formed by the outside of tubular sheath 130 and the interior of walls of block 133 towards underlying substrate onto which the vapor is deposited as a film.

The embodiments described above are offered by way of illustration and example. It should be understood that the examples provided above may be altered in certain respects and still remain within the scope of the claims. It should be appreciated that, while the invention has been described with reference to the above preferred embodiments, other embodiments are within the scope of the claims.

What is claimed is:

1. A vapor distributor assembly comprising:
a heating element configured to provide a temperature sufficient to vaporize at least a portion of a solid material to form a vapor, the heating element comprising a carbon-based structure.

2. The vapor distributor assembly of claim 1, wherein the carbon-based structure comprises carbon fiber.

3. The vapor distributor assembly of claim 1, wherein the carbon-based structure comprises carbon nanotubes.

4. The vapor distributor assembly of claim 1, wherein the heating element is configured to be resistively heated through application of a current.

5. The vapor distributor assembly of claim 1, wherein the heating element is housed within a first chamber.

6. The vapor distributor assembly of claim 5, wherein the heating element is configured to maintain the first chamber at a temperature of about 400 degrees C. or more.

7. The vapor distributor assembly of claim 5, wherein the heating element is configured to maintain the first chamber at a temperature of about 800 degrees C. or less.

8. The vapor distributor assembly of claim 5, wherein the first chamber is configured to receive a solid material and a carrier gas.

9. The vapor distributor assembly of claim 5, wherein the first chamber comprises one or more distribution holes.

10. The vapor distributor assembly of claim 5, further comprising a second chamber substantially proximate to the first chamber, and configured to provide a material flow sufficiently indirect to mix the vapor and the carrier gas into a substantially uniform gas composition.

11. The vapor distributor assembly of claim 10, wherein the first and second chambers are substantially tubular, and the first chamber is disposed within the second chamber such that the second chamber sheaths the first chamber.

12. The vapor distributor assembly of claim 10, wherein the second chamber comprises one or more distribution holes.

13. The vapor distributor assembly of claim 10, wherein the first chamber is configured such that substantially no solid material can be directed into the second chamber.

14. A method for depositing material on a substrate, the method comprising:
introducing a solid material and a carrier gas into a first chamber, the first chamber comprising a heating element; and
resistively heating the heating element to vaporize the solid material into a vapor, wherein the heating element comprises a carbon-based structure selected from the group consisting of carbon nanotubes and carbon fiber.

15. The method of claim 14, further comprising directing a mixture of the vapor and carrier gas through a second chamber.

16. The method of claim 15, wherein directing the mixture of vapor and carrier gas forms a substantially uniform gas composition.

17. The method of claim 14, further comprising directing the substantially uniform gas composition toward a surface of a substrate having a temperature lower than the vapor.

18. A system for depositing a film on a substrate comprising:
a material source connected to a distributor assembly such that a solid material and carrier gas supplied by the material source are introduced into the distributor assembly, wherein the distributor assembly includes:
a first chamber, such that the solid material and carrier gas introduced into the distributor assembly are directed into the first chamber;
a heating element positioned within the first chamber and providing a temperature high enough that at least a portion of the solid material vaporizes into a vapor, wherein the heating element comprises a plurality of carbon-based structures selected from the group consisting of carbon fibers and carbon nanotubes;
a second chamber proximate to the first chamber and providing a material flow sufficiently indirect to mix the vapor and the carrier gas into a substantially uniform vaporlcarrier gas composition; and
an outlet proximate to the second chamber and positioned in a manner that the uniform vaporlcarrier gas composition toward a surface of a proximate substrate; and
a conveyor for transporting the substrate sufficiently proximate to the distributor assembly such that the vapor may be deposited on the substrate as a film.

19. A method of manufacturing a photovoltaic module comprising:
positioning a substrate at a substrate position within a process chamber;
introducing a solid material and a carrier gas into a first chamber, the first chamber comprising a heating element and positioned adjacent to the process chamber;
heating the heating element to vaporize the solid material into a vapor, wherein the heating element comprises a plurality of carbon-based structures selected from the group consisting of carbon nanotubes and carbon fibers;
directing a mixture of the vapor and carrier gas through a second chamber;
forming a substantially uniform gas composition from the vapor and carrier gas; and
directing the substantially uniform gas composition into the process chamber and toward a surface of the substrate, wherein the substrate has a temperature lower than the vapor, to deposit a film comprising the solid material on the substrate.

20. The method of claim 19, wherein the solid material comprises cadmium telluride.

21. The method of claim 19, further comprising depositing one or more additional layers adjacent to the layer of solid material deposited on the substrate.

22. The method of claim 19, further comprising forming a back contact layer adjacent to the layer of solid material deposited on the substrate.

23. The method of claim 22, further comprising positioning at least one common conductor adjacent to the back contact layer.

24. The method of claim 23, further comprising positioning a back cover adjacent to the back contact layer.

25. The method of claim 24, further comprising accessing the at least one common conductor through an opening on the back cover.

26. The method of claim 25, further comprising positioning a junction box adjacent to the back cover.

27. A method of manufacturing a vapor distributor assembly comprising positioning a heating element comprising a carbon-based structure adjacent to a first chamber.

28. The method of claim 27, wherein positioning the heating element adjacent to a first chamber comprises positioning the heating element at least partially within the interior of the first chamber.

29. The method of claim 27, further comprising positioning a second heating element adjacent to a second chamber.

30. The method of claim 27, further comprising positioning a material source adjacent to the first chamber to create a material flow path between the material source and the first chamber.

31. The method of claim 27, further comprising positioning the first chamber adjacent to a substrate process chamber configured to accept a substrate to accept material from the first chamber.

32. The method of claim 31, wherein the step of positioning the first chamber adjacent to the substrate process chamber comprises positioning the first chamber at least partially within the interior of the process chamber.

33. A method of creating a heating element comprising arranging one or more carbon-based structures into the form of a heating element, wherein the one or more carbon-based structures are selected from the group consisting of carbon nanotubes and carbon fibers.

34. The method of claim 33, further comprising the step of forming the carbon-based structures before creating the heating element.

35. The method of claim 34, wherein the step of forming the carbon-based structures comprises arranging a plurality of carbon atoms into the carbon-based structures.

36. The method of claim 22, further comprising fixing the carbon atoms into carbon-based structures after arranging the carbon atoms.

37. A vapor distributor assembly comprising:
a heating element configured to provide a temperature sufficient to vaporize at least a portion of a solid material to form a vapor, the heating element comprising a fiber.

38. The vapor distributor assembly of claim 37, wherein the fiber comprises a carbon fiber.

39. The vapor distributor assembly of claim 37, wherein the fiber comprises a glass fiber.

40. The vapor distributor assembly of claim 37, further comprising at least one chamber adjacent to the heating element, wherein the at least one chamber is configured to direct a vaporized solid material and carrier gas toward a substrate.
